(19) United States
(12) Patent Application Publication
(10) Pub. No.: US 2022/0188495 A1
(43) Pub. Date: Jun. 16, 2022

(54) PHYSICAL PARAMETER GENERATOR

(71) Applicant: Global Mixed-mode Technology Inc., Hsin-Chu (TW)

(72) Inventor: Chih-Chia Chen, Hsinchu County (TW)

(21) Appl. No.: 17/121,777

(22) Filed: Dec. 15, 2020

(51) Int. Cl. G06F 30/367; G06F 30/373

(52) U.S. Cl. CPC G06F 30/367; G06F 30/373

(57) ABSTRACT

A physical parameter generator is configured to generate physical parameter information. The physical parameter generator comprises a physical parameter unit, a current source, and a function pin. The physical parameter unit is coupled to the current source for generating an output signal, where the output signal is related to the physical parameter information. The current source is coupled to the function pin for outputting the physical parameter information. When the function pin is in a floating state, the physical parameter generator may generate the physical parameter information by the function pin.

### BACKGROUND OF THE INVENTION

### 1. Field of the Invention

The present invention relates to a physical parameter generator, and more particularly, to a physical parameter generator which may generate physical parameter information by a function pin.

### 2. Description of the Prior Art

With the development of the electronic engineering technology, a complicated circuit can be integrated into an integrated circuit. In order to allocate more integrated circuits in a limited circuit board space, the integrated circuit designer is often required to generate the needed functions in a limited pin count. Generally speaking, the user may accurately control the characteristics and functions of the electronic apparatus by extracting physical parameter information. However, it indicates that an extra pin is needed in the integrated circuit for outputting the physical parameter information. Since the pin count is related to the package cost, the pin count should be reduced to save the cost and make the product more competitive. Thus, it has become an important issue to make good use of currently available pins for obtaining the needed physical parameter information.

### SUMMARY OF THE INVENTION

According to the present invention, a physical parameter generator which may generate physical parameter information by a function pin is provided. The physical parameter generator may be a part of an integrated circuit. The physical parameter generator comprises a physical parameter unit, a current source, and the function pin. The physical parameter unit is coupled to the current source for generating an output signal, where the output signal is related to the physical parameter information. The current source is coupled to the function pin for outputting the physical parameter information. When the function pin is in a floating state, the physical parameter generator may generate the physical parameter information by the function pin. When the function pin performs a function in a normal mode, the physical parameter generator may output the physical parameter information simultaneously by the function pin. The physical parameter information may be related to a temperature, acceleration, rotational speed, or pressure. The designer may design the physical parameter unit according to different applications, so as to obtain the needed physical parameter information.

The physical parameter unit comprises a bipolar transistor and an amplifying circuit. The bipolar transistor has an emitter, a base, and a collector. The collector of the bipolar transistor is coupled to a voltage source. The base of the bipolar transistor is coupled to the amplifying circuit. The emitter of the bipolar transistor is coupled to a ground. The amplifying circuit is coupled to the bipolar transistor for generating the output signal. For example, when the amplification ratio of the amplifying circuit is 10, since the voltage difference between the base and the emitter varies with the temperature by a factor of 2 mV/° C., the output signal varies with the temperature by a factor of 20 mV/° C.

When the function pin is an enable pin and the enable pin is in a floating state, the enable pin is pulled high to the level of the output signal by the current source. At this moment the integrated circuit is enabled and the temperature information may be obtained simultaneously by measuring the voltage of the enable pin. When the function pin is the enable pin and the enable pin is pulled to a low level, the integrated circuit is disabled. Thus, the enable pin may perform an enable function and provide the needed temperature information simultaneously.

According to one embodiment of the present invention, the advantage is that it does not need an extra pin since the physical parameter information is generated by the function pin. Furthermore, the integrated circuit is not in a test mode when outputting the physical parameter information, such that it may avoid wrongly entering the test mode to result in the malfunction of the integrated circuit. When the function pin is in a floating state, the physical parameter generator may generate the physical parameter information by the function pin. When the function pin performs a function in a normal mode, the physical parameter generator may output the physical parameter information simultaneously by the function pin. The physical parameter information may be related to a temperature, acceleration, rotational speed, or pressure. The designer may design the physical parameter unit according to different applications, so as to obtain the needed physical parameter information.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The above-mentioned and other objects, features, and advantages of the present invention will become apparent with reference to the following descriptions and accompanying drawings, wherein:

FIG. 1 is a schematic diagram showing a physical parameter generator according to one embodiment of the present invention; and

FIG. 2 is a schematic diagram showing a physical parameter unit according to one embodiment of the present invention.

### DETAILED DESCRIPTION

Preferred embodiments according to the present invention will be described in detail with reference to the drawings.

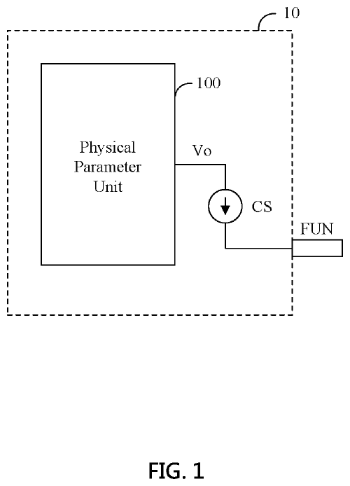

FIG. 1 is a schematic diagram showing a physical parameter generator 10 according to one embodiment of the present invention. The physical parameter generator 10 may be a part of an integrated circuit. The physical parameter generator 10 comprises a physical parameter unit 100, a current source CS, and a function pin FUN, where the physical parameter generator 10 generates physical parameter information by the function pin FUN. The physical parameter unit 100 is coupled to the current source CS for generating an output signal Vo, where the output signal Vo is related to the physical parameter information. The current source CS is coupled to the function pin FUN for outputting the physical parameter information. When the function pin FUN is in a floating state, the physical parameter generator 10 may generate the physical parameter information by the function pin FUN. When the function pin FUN performs a function in a normal mode, the physical parameter generator 10 may output the physical parameter information simultaneously by the function pin FUN. The physical parameter information may be related to a temperature, acceleration, rotational speed, or pressure. The designer may design the physical parameter unit 100 according to different applications, so as to obtain the needed physical parameter information.

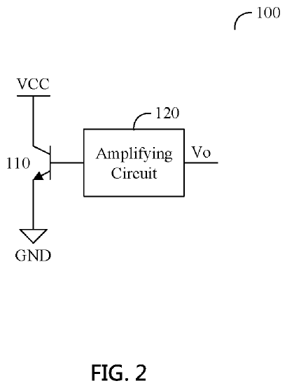

According to one embodiment of the present invention, the function pin FUN may be an enable pin and the physical parameter unit 100 may be a temperature sensor. FIG. 2 is a schematic diagram showing a physical parameter unit 100 according to one embodiment of the present invention. The physical parameter unit 100 comprises a bipolar transistor 110 and an amplifying circuit 120. The bipolar transistor 110 has an emitter, a base, and a collector. The collector of the bipolar transistor 110 is coupled to a voltage source VCC. The base of the bipolar transistor 110 is coupled to the amplifying circuit 120. The emitter of the bipolar transistor 110 is coupled to a ground GND. The amplifying circuit 120 is coupled to the bipolar transistor 110 for generating the output signal Vo. For example, when the amplification ratio of the amplifying circuit 120 is 10, since the voltage difference between the base and the emitter varies with the temperature by a factor of 2 mV/° C., the output signal Vo varies with the temperature by a factor of 20 mV/° C. As shown in FIG. 2, the bipolar transistor 110 may be an NPN bipolar transistor. Furthermore, the output signal Vo is related to the physical parameter information (e.g., temperature).

Please refer to FIG. 1 and FIG. 2 simultaneously. When the function pin FUN is the enable pin and the enable pin is in a floating state, the enable pin is pulled high to the level of the output signal Vo by the current source CS. At this moment the integrated circuit is enabled and the temperature information may be obtained simultaneously by measuring the voltage of the enable pin. When the function pin FUN is the enable pin and the enable pin is pulled to a low level, the integrated circuit is disabled. Thus, the enable pin may perform an enable function and provide the needed temperature information simultaneously. Since most integrated circuits allocate an enable pin, the enable pin is selected as an example.

According to one embodiment of the present invention, the advantage is that it does not need an extra pin since the physical parameter information is generated by the function pin FUN. Furthermore, the integrated circuit is not in a test mode when outputting the physical parameter information, thereby avoiding the mistakenly started test mode which results in the malfunction of the integrated circuit. When the function pin FUN is in a floating state, the physical parameter generator 10 may generate the physical parameter information by the function pin FUN. When the function pin FUN performs a function in a normal mode, the physical parameter generator 10 may output the physical parameter information simultaneously by the function pin FUN. The physical parameter information may be related to a temperature, acceleration, rotational speed, or pressure. The designer may design the physical parameter unit 100 according to different applications, so as to obtain the needed physical parameter information.

While the present invention has been described by the preferred embodiment, it is to be understood that the invention is not limited to the disclosed embodiment. On the contrary, it is intended to cover various modifications. Therefore, the scope of the appended claims should be accorded the broadest interpretation so as to encompass all such modifications.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A physical parameter generator configured to generate physical parameter information, the physical parameter generator comprising:
a function pin;
a current source, coupled to the function pin for outputting the physical parameter information; and
a physical parameter unit, coupled to the current source for generating an output signal, wherein the output signal is related to the physical parameter information, and when the function pin is in a floating state, the physical parameter generator generates the physical parameter information by the function pin.

2. The physical parameter generator of claim 1, wherein the physical parameter information is related to a temperature.

3. The physical parameter generator of claim 1, wherein when the function pin performs a function, the physical parameter generator outputs the physical parameter information simultaneously by the function pin.

4. The physical parameter generator of claim 1, wherein the function pin is an enable pin.

5. The physical parameter generator of claim 1, wherein the physical parameter unit comprises a bipolar transistor.

6. The physical parameter generator of claim 5, wherein the bipolar transistor is an NPN bipolar transistor.

7. The physical parameter generator of claim 5, wherein the physical parameter unit further comprises an amplifying circuit, and the amplifying circuit is coupled to the bipolar transistor for generating the output signal.

8. The physical parameter generator of claim 1, wherein the physical parameter generator is a part of an integrated circuit.

9. The physical parameter generator of claim 8, wherein the integrated circuit is not in a test mode when outputting the physical parameter information.
